(19) United States
(12) Patent Application Publication
(10) Pub. No.: US 2019/0374982 A1
(43) Pub. Date: Dec. 12, 2019

(54) METHOD FOR TREATING SUBSTRATE AND RINSING LIQUID

(71) Applicant: TOKYO OHKA KOGYO CO., LTD., Kawasaki-shi (JP)

(72) Inventors: Takumi NAMIKI, Kawasaki-shi (JP); Daijiro MORI, Kawasaki-shi (JP)

(21) Appl. No.: 16/427,845

(22) Filed: May 31, 2019

Related U.S. Application Data
(60) Provisional application No. 62/681,095, filed on Jun. 6, 2018.

(51) Int. Cl. B08B 3/08; B08B 3/04; H01L 21/02

(52) U.S. Cl. CPC B08B 3/08; H01L 21/02057; B08B 3/041

(57) ABSTRACT

Provided are a method for treating a substrate, including rinsing a surface of a substrate in which a pattern having an aspect ratio of 10 or more is provided on the surface with a rinsing liquid, in which the rinsing liquid includes an organic solvent (S1) having a vapor pressure at 20° C. of 25 mmHg or less; and a rinsing liquid for rinsing the surface of the substrate in which a pattern having an aspect ratio of 10 or more is provided on the surface, including an organic solvent (S1) having a vapor pressure at 20° C. of 25 mmHg or less.

Priority is claimed on U.S. Patent Application, Publication No. 62/681,095, filed on Jun. 6, 2018, the entire content of which is incorporated herein by reference.

### BACKGROUND OF THE INVENTION

### Field of the Invention

The present invention relates to a method for treating a substrate and a rinsing liquid.

### Description of Related Art

In recent years, rapid miniaturization of a pattern has proceeded with a progress of lithography technology in the production of a semiconductor element or a liquid crystal display element. An aspect ratio of the pattern tends to increase with the miniaturization of the pattern.

On the other hand, in a process for producing a semiconductor, incorporation of particles or the like causes a reduction in a production yield. As a result, a substrate is washed with a rinsing liquid in order to remove particles and the like that adhere onto the substrate. After washing the substrate with the rinsing liquid, the rinsing liquid is removed by drying the substrate, but at this time, pattern collapse occurs in some cases by the capillary force of the rinsing liquid remaining in the pattern.

In order to avoid the problem of pattern collapse, a method for treating a surface of a substrate with a water repellent agent and then washing the substrate with a rinsing liquid such as 2-isopropanol has been proposed (for example, Japanese Unexamined Patent Application, First Publication No. 2010-192878 and Japanese Unexamined Patent Application, First Publication No. 2016-72446).

### SUMMARY OF THE INVENTION

In a substrate having a pattern having a high aspect ratio, pattern collapse more easily occurs upon washing and drying the substrate, and even in a case where a water repellent treatment is performed, the pattern collapse cannot be sufficiently suppressed in some cases. In this regard, there has been a demand for a rinsing liquid which is capable of suppressing pattern collapse more effectively.

The present invention has been made in consideration of such circumstances and has an object to provide a method for treating a substrate, capable of suppressing pattern collapse in a substrate on which a pattern having a high aspect ratio is provided, and a rinsing liquid used in the method.

The present invention adopts the following configurations in order to solve the above-mentioned problems.

That is, a first aspect of the present invention is a method for treating a substrate, including rinsing a surface of the substrate in which a pattern having an aspect ratio of 10 or more is provided on the surface with a rinsing liquid, in which the rinsing liquid includes an organic solvent (S1) having a vapor pressure at 20° C. of 25 mmHg or less.

A second aspect of the present invention is a rinsing liquid for rinsing a surface of a substrate in which a pattern having an aspect ratio of 10 or more is provided on the surface, including an organic solvent (S1) having a vapor pressure at 20° C. of 25 mmHg or less.

According to the present invention, a method for treating a substrate, capable of suppressing pattern collapse in a substrate on which a pattern having a high aspect ratio is provided, and a rinsing liquid used in the method are provided.

### BRIEF DESCRIPTION OF THE DRAWING

FIG. 1 is a vertical cross-sectional view of a substrate on which a pattern including a plurality of pillars is provided.

### DETAILED DESCRIPTION OF THE INVENTION

Method for Treating Substrate

A method for treating a substrate according to the first aspect of the present invention is a method for treating a substrate, including a step of rinsing a surface of the substrate in which a pattern having an aspect ratio of 10 or more is provided on the surface with a rinsing liquid. The rinsing liquid may include an organic solvent (S1) having a vapor pressure at 20° C. of 25 mmHg or less.

The method for treating a substrate according to the present aspect is applied to a substrate in which a pattern having an aspect ratio of 10 or more is provided on the surface. It is possible to suppress pattern collapse by rinsing the surface of the substrate with a rinsing liquid including an organic solvent (S1) having a vapor pressure at 20° C. of 25 mmHg or less.

Hereinafter, the method for treating a substrate according to the present aspect will be described in detail.

Rinsing Step

The rinsing step is a step of rinsing a surface of a substrate in which a pattern having an aspect ratio of 10 or more is provided on the surface with a rinsing liquid. As the rinsing liquid, a rinsing liquid including an organic solvent (S1) having a vapor pressure at 20° C. of 25 mmHg or less is used.

The substrate is not particularly limited, and a substrate known in the related art can be used. Examples of the substrate include a substrate for an electronic part or a substrate on which a predetermined wiring pattern is formed. More specific examples thereof include a silicon wafer, a substrate made of a metal such as copper, chromium, iron, and aluminum, and a glass substrate. As a material for the wiring pattern, for example, copper, aluminum, nickel, gold, or the like can be used.

Among those, the substrate is preferably a silicon wafer (silicon substrate). The silicon substrate may have a silicon oxide film such as a natural oxide film, a thermal oxide film, and a vapor phase synthetic film (CVD film or the like) on the surface thereof, or may have a pattern formed on the silicon oxide film.

The substrate used in the method for treating a substrate according to the present aspect has a pattern having an aspect ratio of 10 or more provided on the surface of such the substrate. The pattern is provided as a fine concavity and convexity shape on the surface of the substrate. The aspect ratio of the pattern is determined as a ratio (height/width) of the height of the convex portion to the width of the convex portion of the pattern.

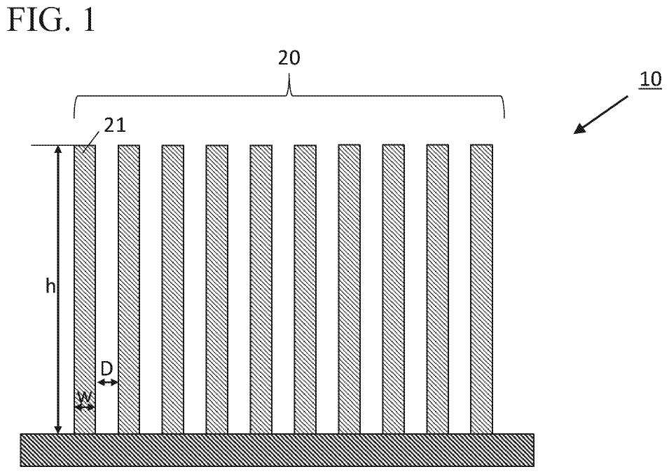

For example, FIG. 1 shows a vertical cross-sectional view of a substrate 10 in which a pattern 20 including a plurality of pillars 21 is provided on the surface. In the pattern 20 illustrated in FIG. 1, the aspect ratio is determined as a ratio (h/w) of the height (h) of the pillar 21 to the width (w) of the pillar 21. In addition, for example, in a case of a line-and-space pattern, the aspect ratio is determined as a ratio (h/w) of the height (h) of the line to the width (w) of the line.

In a case where the aspect ratio of the pattern is 10 or more, it is not particularly limited and exemplified by 10 to 40, for example. The aspect ratio of the pattern is preferably 12 to 30, and more preferably 15 to 25.

Examples of the pattern having such an aspect ratio include a pattern having a width of 20 to 100 nm and a height of 200 to 10,000 nm.

In a case where there is a difference in the width between the top and the bottom of the pattern (in a case where the pattern is in a tapered shape or an inverted tapered shape), a value of the width of the bottom can be adopted as the above-mentioned w.

The interval of the patterns is not particularly limited, but is preferably 150 nm or less. For example, in an example shown in FIG. 1, the interval of the patterns 20 is represented by a distance D between pillars 21. Further, for example, in a case of a line-and-space pattern, the interval of the patterns is referred to a size of the space (distance between the lines). The interval between the patterns is exemplified by 30 to 120 nm, and preferably 40 to 100 nm.

The pattern shape is not particularly limited and can be a pattern shape that is generally formed in a semiconductor manufacturing process. The pattern shape may be either a line pattern or a hole pattern, or may also be a pattern including a plurality of pillars. The pattern shape is preferably a pattern including a plurality of pillars. The shape of the pillar is not particularly limited, but examples thereof include a columnar shape and a polygonal columnar shape (square columnar shape and the like).

Formation of such a pattern can be performed using a known method. For example, a pattern can be formed by forming a resist film on a substrate using a known resist composition, exposing and developing the resist film to form a resist pattern, and then etching the substrate using the resist pattern as a mask.

In the rinsing step, the surface of the substrate in which such the pattern is provided is rinsed with a rinsing liquid which will be described later. The rinsing method is not particularly limited, and a method generally used for washing a substrate in a semiconductor manufacturing process can be adopted. Examples of such a method include a method in which a substrate is immersed in a rinsing liquid, a method in which a vapor of a rinsing liquid is brought into contact with a substrate, and a method in which a rinsing liquid is supplied to a substrate while the substrate is spun. Among those, as the rinsing method, the method in which a rinsing liquid is supplied to a substrate while the substrate is spun is preferable. In the method, the rotation speed in the spinning is exemplified by 100 to 5,000 rpm, for example.

Rinsing Liquid

In the rinsing step, a rinsing liquid including an organic solvent (S1) having a vapor pressure at 20° C. of 25 mmHg or less is used. It is possible to suppress pattern collapse by performing the rinsing step using the rinsing liquid even in a case where the pattern has an aspect ratio of 10 or more.

Organic Solvent (S1)

The organic solvent (S1) is not particularly limited in a case where it has a vapor pressure at 20° C. of 25 mmHg or less. It is possible to suppress pattern collapse effectively by using an organic solvent having a vapor pressure of the above upper limit value or less. The vapor pressure at 20° C. is preferably 17 mmHg or less. The lower limit value of the vapor pressure at 20° C. is not particularly limited, but is preferably 1 mmHg or more from the viewpoint of the suppression of pattern collapse. A preferred range of the vapor pressure at 20° C. of the organic solvent (S1) is exemplified by 1 to 25 mmHg, and the vapor pressure is preferably 3 to 17 mmHg, more preferably 4 to 16 mmHg, still more preferably 10 to 16 mmHg, and particularly preferably 13 to 16 mmHg.

Furthermore, a preferred example of the organic solvent (S1) is a solvent having a surface tension at 20° C. of 70 dyn/cm or less. The surface tension at 20° C. is preferably 60 dyn/cm or less, more preferably 50 dyn/cm or less, and more preferably 40 dyn/cm or less. In a case where the surface tension of the organic solvent (S1) is the above upper limit value or less, it is possible to suppress pattern collapse effectively in the rinsing step. The lower limit value of the surface tension at 20° C. is not particularly limited, but is exemplified by 10 dyn/cm or more, for example. The surface tension at 20° C. is preferably 10 to 70 dyn/cm, more preferably 10 to 60 dyn/cm, still more preferably 10 to 50 dyn/cm, and particularly preferably 10 to 40 dyn/cm.

Specific examples of the organic solvent (S1) suitably include 2-butanol, 2-methyl-2-propanol, 1-propanol, 1-butanol, and propylene glycol. Among these, 2-butanol, 1-propanol, and 1-butanol are preferable.

The organic solvent (S1) may be used singly or in combination of two or more kinds thereof.

A ratio of the organic solvent (S1) in the rinsing liquid is preferably 20% to 100% by mass, more preferably 30% to 100% by mass, and still more preferably 40% to 100% by mass. In a case where the ratio of the organic solvent (S1) is the lower limit value or more of the above preferred range, it is possible to suppress pattern collapse more effectively.

Optional Components The rinsing liquid may include other components, in addition to the organic solvent (S1). Examples of such other components include an organic solvent (S2) other than the organic solvents (S1). Examples of the organic solvent (S2) include hydrocarbons, esters, ethers, ketones, halogen-containing solvents, sulfoxide-based solvents, alcohols, derivatives of polyhydric alcohols, and nitrogen-containing compound solvents.

Among those, the organic solvent (S2) is preferably an alcohol. Specific examples thereof include methanol, ethanol, and 2-isopropanol.

The organic solvent (S2) may be used singly or in combination of two or more kinds thereof.

The ratio of the organic solvent (S2) in the rinsing liquid is preferably 0% to 80% by mass, more preferably 0% to 70% by mass, and more preferably 0% to 60% by mass. In a case where the ratio of the organic solvent (S2) is the upper limit value or less of the above preferred range, it becomes easy to balance the organic solvent (S1).

The ratio (mass ratio) of the organic solvent (S2) to the organic solvent (S1), organic solvent (S1)/organic solvent (S2), is preferably 20/80 to 100/0, more preferably 30/70 to 100/0, still more preferably 40/60 to 100/0, and particularly preferably 50/50 to 100/0.

In addition, examples of optional components include a surfactant.

Examples of the surfactant include a fluorine-based surfactant and a silicone-based surfactant.

Specific examples of the fluorine-based surfactant include, but are not limited to, commercially available fluorine-based surfactants such as BM-1000 and BM-1100 (both manufactured by BM Chemie), MEGAFAC F142D, MEGAFAC F172, MEGAFAC F173, and MEGAFAC F183 (all manufactured by DIC Corporation), FLUORAD FC-135, FLUORAD FC-170C, FLUORAD FC-430, and FLUORAD FC-431 (all manufactured by Sumitomo 3M Co., Ltd.), SURFLON S-112, SURFLON S-113, SURFLON S-131, SURFLON S-141, and SURFLON S-145 (all manufactured by Asahi Glass Co., Ltd.), and SH-28PA, SH-190, SH-193, SZ-6032, and SF-8428 (all manufactured by Dow Corning Toray Silicone Co., Ltd.).

As the silicone-based surfactant, an unmodified silicone-based surfactant, a polyether-modified silicone-based surfactant, a polyester-modified silicone-based surfactant, an alkyl-modified silicone-based surfactant, an aralkyl-modified silicone-based surfactant, a reactive silicone-based surfactant, or the like can be preferably used.

As the silicone-based surfactant, a commercially available silicone-based surfactant can be used. Specific examples of the commercially available silicone-based surfactant include PEINTAD M (manufactured by Dow Corning Toray Co., Ltd.), TOPICA K1000, TOPICA K2000, and TOPICA K5000 (all manufactured by Takachiho Sangyo Co., Ltd.), XL-121 (polyether-modified silicone-based surfactant, manufactured by Clariant Co., Ltd.), and BYK-310 (polyester-modified silicone-based surfactant, manufactured by BYK-Chemie).

In addition, known anionic surfactants, cationic surfactants, non-ionic surfactants other than the above-mentioned fluorine-based surfactants and silicone-based surfactants, or the like can also be used as the surfactant.

Optional Steps

The method for treating a substrate according to the present aspect may include other steps, in addition to the rinsing step. Examples of such other steps include a hydrophobizing step and a drying step.

Hydrophobizing Step

The hydrophobizing step is a step of hydrophobizing the surface of the pattern. In the method for treating a substrate according to the present aspect, the hydrophobizing step may be performed before the rinsing step. Moisture is suppressed from remaining in a concave portion of the pattern by performing the hydrophobizing step, which is thus effective for the suppression of pattern collapse.

Hydrophobization of the surface of the pattern can be performed by treating the surface of the pattern using a water repellent. The water repellent used in the water repellent step is not particularly limited, and according to the materials of a substrate, a material generally used for a hydrophobization treatment can be appropriately selected and used. Suitable examples of the water repellent include a water repellent containing a silylating agent.

The silylating agent is not particularly limited, and any of silylating agents known in the related art can be used. Specifically, for example, a silylating agent represented by each of General Formulae (1) to (3) can be used. In General Formulae (1) to (3), the alkyl group has 1 to 5 carbon atoms, the cycloalkyl group has 5 to 10 carbon atoms, the alkoxy group has 1 to 5 carbon atoms, and the heterocycloalkyl group has 5 to 10 carbon atoms.

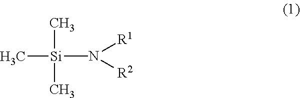

[In Formula (1), R¹ represents a hydrogen atom, or saturated or unsaturated alkyl group, and R² represents a saturated or unsaturated alkyl group, a saturated or unsaturated cycloalkyl group, or a saturated or unsaturated heterocycloalkyl group. R¹ and R² may be bonded to each other to form a saturated or unsaturated heterocycloalkyl group having a nitrogen atom.]

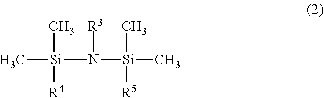

[In Formula (2), R³ represents a hydrogen atom, a methyl group, a trimethylsilyl group, or a dimethylsilyl group, and R⁴ and R⁵ each independently represent a hydrogen atom, an alkyl group, or a vinyl group.]

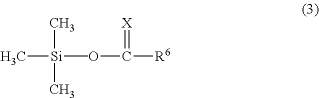

[In Formula (3), X represents O, CHR⁷, CHOW, CR⁷R⁷, or NR⁸, R⁶ and R⁷ each independently represent a hydrogen atom, a saturated or unsaturated alkyl group, a saturated or unsaturated cycloalkyl group, a trialkylsilyl group, a trialkylsiloxy group, an alkoxy group, a phenyl group, a phenethyl group, or an acetyl group, and R⁸ represents a hydrogen atom, an alkyl group, or a trialkylsilyl group.]

Examples of the silylating agent represented by Formula (1) include N,N-dimethylaminotrimethylsilane, N,N-diethylaminotrimethylsilane, t-butylaminotrimethylsilane, allylaminotrimethylsilane, trimethylsilylacetamide, trimethylsilylpiperidine, trimethylsilylimidazole, trimethylsilylmorpholine, 3-trimethylsilyl-2-oxazolidinone, trimethylsilylpyrazole, trimethylsilylpyrrolidine, 2-trimethylsilyl-1,2,3-triazole, and 1-trimethylsilyl-1,2,4-triazole.

Furthermore, examples of the silylating agent represented by Formula (2) include hexamethyldisilazane, N-methylhexamethyldisilazane, 1,2-di-N-octyltetramethyldisilazane, 1,2-divinyltetramethyldisilazane, heptamethyldisilazane, nonamethyltrisilazane, and tris(dimethylsilyl)amine.

Moreover, examples of the silylating agent represented by Formula (3) include trimethylsilyl acetate, trimethylsilyl propionate, trimethylsilyl butyrate, and trimethylsilyloxy-3-penten-2-one.

The silylating agent can be used after being dissolved in an appropriate solvent. The solvent for the silylating agent is not particularly limited, and a solvent which can dissolve the silylating agent and is less likely to cause damage on patterns can be appropriately selected and used.

Specific examples of the solvent for the silylating agent include sulfoxides such as dimethyl sulfoxide; sulfones such as dimethylsulfone, diethylsulfone, bis(2-hydroxyethyl)sulfone, and tetramethylenesulfone; amides such as N,N-dimethylformamide, N-methylformamide, N,N-dimethylacetamide, N-methylacetamide, and N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; dialkyl ethers such as dimethyl ether, diethyl ether, methylethyl ether, dipropyl ether, diisopropyl ether, and dibutyl ether; dialkyl glycol ethers such as dimethyl glycol, dimethyl diglycol, dimethyl triglycol, methylethyl diglycol, and diethyl glycol; ketones such as methyl ethyl ketone, cyclohexanone, 2-heptanone, and 3-heptanone; terpenes such as p-menthane, diphenyl menthane, limonene, terpinene, bornane, norbornane, and pinane; polyhydric alcohols such as ethylene glycol, diethylene glycol, propylene glycol, and dipropylene glycol; and derivatives of polyhydric alcohols [propylene glycol monomethyl ether acetate (PGMEA), propylene glycol monomethyl ether (PGME), and the like], such as compounds having an ester bond, such as ethylene glycol monoacetate, diethylene glycol monoacetate, propylene glycol monoacetate, and dipropylene glycol monoacetate, compounds having an ether bond, such as monoalkyl ethers or monophenyl ethers such as monomethyl ether, monoethyl ether, monopropyl ether, monobutyl ether, and the like of the polyhydric alcohols or the compounds having an ester bond.

The concentration of the silylating agent in the water repellent is exemplified by 0.1% to 50% by mass, and the concentration is more preferably 0.5% to 30% by mass, and still more preferably 1.0% to 20% by mass. Within the above-mentioned range, the hydrophobicity of the surface of the pattern can be sufficiently enhanced while securing the coatability of the silylating agent.

Treatment of the surface of the pattern with a water repellent can be performed by contacting a surface of a substrate on which a pattern is provided with a water repellent. Examples of such a method include a method in which a substrate is immersed in a water repellent, a method in which a vapor of a water repellent is contacted with a surface of a pattern, and a method in which a water repellent is supplied to a surface of a pattern while a substrate is spun.

Drying Step

The drying step is a step of drying the substrate. In the method for treating a substrate according to the present aspect, the drying step may be performed after the rinsing step. By performing the drying step, the rinsing liquid remaining in the substrate after the rinsing step can be efficiently removed.

A method for drying the substrate is not particularly limited, and a known method such as spin drying, heating drying, hot air drying, and vacuum drying can be used. For example, spin drying with a blow of inert gas (nitrogen gas or the like) is suitably exemplified.

According to the method for treating a substrate according to the present aspect, pattern collapse can be effectively suppressed by using a rinsing liquid including an organic solvent (S1) having a vapor pressure at 20° C. of 25 mmHg or less in a treatment of a substrate having a pattern having an aspect ratio of 10 or more.

In the related art, a rinsing liquid including 2-isopropanol and the like has been used for the rinsing of a substrate. However, with regard to the rinsing liquid in the related art, in a case where the rinsing liquid is used for a pattern having an aspect ratio of 10 or more, it was not possible to sufficiently suppress pattern collapse even with the hydrophobization of a surface of a pattern with a water repellent. This is considered to be caused by a tendency that since the vapor pressure of 2-isopropanol is high (32 mmHg at 20° C.), moisture incorporated into the rinsing liquid from air or the like remains in the concave portion of the pattern rather than 2-isopropanol. That is, it is presumed that a surface tension of the water remaining in the concave portion of the pattern causes pattern collapse after the rinsing step.

On the other hand, in the method for treating a substrate according to the present aspect, it is considered that water incorporated into the concave portion of the pattern is suppressed from remaining since the rinsing liquid including an organic solvent (S1) having a vapor pressure at 20° C. of 25 mmHg or less is used. Thus, it is presumed that pattern collapse is suppressed.

Rinsing Liquid

The rinsing liquid according to the second aspect of the present invention is a rinsing liquid for rinsing a surface of a substrate in which a pattern having an aspect ratio of 10 or more is provided on the surface, including an organic solvent (S1) having a vapor pressure at 20° C. of 25 mmHg or less.

The rinsing liquid according to the present aspect is the same as the rinsing liquid described for the method for treating a substrate according to the first aspect. The substrate in which a pattern having an aspect ratio of 10 or more is provided on the surface, which is applied to the rinsing liquid according to the present aspect, is the same as the substrate described above.

### EXAMPLES

Hereinafter, the present invention will be described in more detail with reference to Examples, but the present invention is not limited to these Examples.

### Examples 1 to 5 and Comparative Examples 1 to 4

Method (1) for Treating Substrate

Hydrophobizing Step

In a substrate, a silicon wafer in 12 inches on which a pattern having pillars having an aspect ratio of 15 is provided at an interval of 50 nm was used. While the substrate was spun (a rotation number of 300 rpm, room temperature (20° C.), and 10 seconds), a surface of the wafer on which a pattern is provided was treated with a water repellent in which dimethylaminotrimethylsilane was dissolved in PGMEA.

Rinsing Step

After the hydrophobization treatment, while the substrate was spun (a rotation number of 1,000 rpm, room temperature (20° C.), and 1 minute), the rinsing liquid of each of Examples shown in Table 1 was supplied to a surface of the substrate on which a pattern is provided, and the surface of the substrate was rinsed.

TABLE 1

| | Rinsing liquid | | |
|---|---|---|---|
| | Organic | Organic | |
| | solvent (S1) | solvent (S2) | Others |
| Example 1 | 2-Butanol | — | — |
| | [100] | | |
| Example 2 | 1-Propanol | — | — |
| | [100] | | |
| Example 3 | 1-Butanol | — | — |
| | [100] | | |
| Example 4 | Propylene glycol | — | — |
| | [100] | | |
| Example 5 | 1-Propanol | 2-Propanol | — |
| | [50] | [50] | |
| Comparative Example 1 | — | — | Water |
| | | | [100] |
| Comparative Example 2 | — | Methanol | — |
| | | [100] | |
| Comparative Example 3 | — | Methyl ethyl | — |
| | | ketone | |
| | | [100] | |
| Comparative Example 4 | — | 2-Propanol | — |
| | | [100] | |

In Table 1, the numerical values in [ ] are blend amounts (parts by mass). The vapor pressures at 20° C. of the respective solvents shown in Table 1 are shown below.

| | | |
|---|---|---|
| 2-Butanol | 12.8 | mmHg |
| 1-Propanol | 15 | mmHg |
| 1-Butanol | 4.5 | mmHg |
| Propylene glycol | 0.08 | mmHg |
| Water | 17.5 | mmHg |
| Methanol | 95 | mmHg |
| Methyl ethyl ketone | 77.5 | mmHg |
| 2-Propanol | 32 | mmHg |

Drying Step

After the rinsing step, the substrate was spin-dried (a rotation number of 1,000 rpm, room temperature (20° C.), and 1 minute) with a blow of nitrogen.

Evaluation (1) of Pattern Collapse

The number of pillars collapsed was counted by acquiring three SEM pictures in each of Examples by means of a critical dimension scanning electron microscope (SEM, an accelerating voltage of 300 V, product name: S-9380, manufactured by Hitachi High-Technologies Corporation). The results are shown in Table 2.

TABLE 2

| | Number of collapses | | |
|---|---|---|---|
| | No. 1 | No. 2 | No. 3 |
| Example 1 | 12 | 18 | 12 |
| Example 2 | 2 | 2 | 0 |
| Example 3 | 14 | 24 | 12 |
| Example 4 | >100 | >100 | >100 |
| Example 5 | 2 | 0 | 2 |
| Comparative Example 1 | >500 | >500 | >500 |
| Comparative Example 2 | >500 | >500 | >500 |
| Comparative Example 3 | >500 | >500 | >500 |
| Comparative Example 4 | >500 | >500 | >500 |

From the results shown in Table 2, it was confirmed that in Examples 1 to 5, pattern collapse was significantly suppressed, as compared with Comparative Examples 1 to 4.

### Example 6 and Comparative Example 5

Method (2) for Treating Substrate

Hydrophobizing Step

By the same method as above, except that a chemical solution in which 1,1,1,3,3,3-hexamethyldisilazane was dissolved in PGMEA was used as the water repellent, the hydrophobizing step was performed.

Rinsing Step

By the same method as above, except that the rinsing liquid of each of Examples shown in Table 3 was used, the rinsing step was performed.

Drying Step

By the same method as above, the drying step was performed.

TABLE 3

| | Rinsing liquid | | |
|---|---|---|---|
| | Organic | Organic | |
| | solvent (S1) | solvent (S2) | Others |
| Example 6 | 1-Propanol | — | — |
| | [100] | | |
| Comparative Example 5 | — | 2-Propanol | — |
| | | [100] | |

Evaluation (2) of Pattern Collapse

The number of pillars collapsed was counted by acquiring three SEM pictures in each of Examples in the same manner as above. The results are shown in Table 4.

TABLE 4

| | Number of collapses | | |
|---|---|---|---|
| | No. 1 | No. 2 | No. 3 |
| Example 6 | 0 | 0 | 4 |
| Comparative Example 5 | 40 | 56 | 40 |

From the results shown in Table 4, it was confirmed that in Example 6, pattern collapse was significantly suppressed, as compared with Comparative Example 5.

### EXPLANATION OF REFERENCES

10 Substrate
20 Pattern
21 Pillar

What is claimed is:

1. A method for treating a substrate, comprising:
rinsing a surface of the substrate in which a pattern having an aspect ratio of 10 or more is provided on the surface with a rinsing liquid,
wherein the rinsing liquid includes an organic solvent (S1) having a vapor pressure at 20° C. of 25 mmHg or less.

2. The method for treating a substrate according to claim 1, wherein the pattern is a pattern including a plurality of pillars having an aspect ratio of 10 or more.

3. The method for treating a substrate according to claim 1, further comprising hydrophobizing a surface of the pattern before the rinsing.

4. The method for treating a substrate according to claim 3, wherein the hydrophobizing is performed by treating the surface of the pattern with a silylating agent.

5. The method for treating a substrate according to claim 1, wherein the rinsing is performed while the substrate is spun.

6. The method for treating a substrate according to claim 1, wherein the organic solvent (S1) has a vapor pressure at 20° C. of 1 mmHg or more.

7. The method for treating a substrate according to claim 1, further comprising drying the substrate on which the pattern is provided after the rinsing.

8. The method for treating a substrate according to claim 1, wherein the substrate is a silicon substrate.

9. A rinsing liquid for rinsing a surface of a substrate in which a pattern having an aspect ratio of 10 or more is provided on the surface, comprising an organic solvent (S1) having a vapor pressure at 20° C. of 25 mmHg or less.

10. The rinsing liquid according to claim 9, wherein the organic solvent (S1) has a vapor pressure at 20° C. of 1 mmHg or more.
